(19) United States
(12) Patent Application Publication
(10) Pub. No.: US 2006/0197163 A1
(43) Pub. Date: Sep. 7, 2006

(54) Semiconductor device and method for manufacturing semiconductor device

(75) Inventor: Juri Kato, Nagano-Ken (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/363,694

(22) Filed: Feb. 27, 2006

(30) Foreign Application Priority Data
Feb. 28, 2005 (JP) 2005-054612

(51) Int. Cl. H01L 29/76; H01L 21/336

(52) U.S. Cl. 257/401; 438/284; 257/E29.028

(57) ABSTRACT

A semiconductor device comprising: a semiconductor layer having a film formation face in a side wall, the side wall being film-formed with epitaxial-growth; a gate electrode arranged on the side wall of the semiconductor layer; a source layer arranged in one side of the gate electrode, the source layer being formed in the semiconductor layer; and a drain layer arranged in other side of the gate electrode, the drain layer being formed in the semiconductor layer.

### BACKGROUND

1. Technical Field

The present invention relates to semiconductor devices and methods for manufacturing semiconductor devices, and in particular, is suitably applied to electric field effect transistors having a channel on a side wall of a semiconductor layer.

2. Related Art

For the conventional semiconductor devices, there is disclosed a method in which the integration degree of transistors is improved while securing the current drive capability by forming a fin structure of Si on a Si substrate and arranging a gate electrode along the side wall of the fin.

Extended Abstract of the 2003 International Conference on Solid State Devices and Materials, Tokyo, 2003, pp. 280-281, is an example of related art.

However, in the conventional fin type transistors, the fin structure to be a channel region is formed with dry etching using a resist pattern as a mask. For this reason, defects occur in the channel region due to the damage at the time of dry etching, thereby inviting the increase of the interface state density and the degradation of mobility, and therefore there is a problem that the electrical characteristics of the electric field effect type transistors deteriorate. Moreover, because the fin structure to be the channel region is formed with photo etching, variation likely occurs in the thickness of the fin, and moreover, the thickness of the fin to be the channel region is restricted by the exposure wavelength at the time of the photo lithography. Thus, a limit to thin-filming of the fin is a concern.

### SUMMARY

An advantage of the invention is to provide semiconductor devices in which it is possible to cause a side wall of a semiconductor layer to have a channel, and possible to stably carry out film-thickness control of the semiconductor layer, in which a channel is to be formed, while suppressing damages in the channel region, and provide methods for manufacturing the semiconductor devices.

According to an aspect of the invention, a semiconductor device includes: a semiconductor layer having a film formation face in a side wall, the side wall being film-formed with epitaxial-growth; a gate electrode arranged on the side wall of the semiconductor layer; a source layer arranged in one side of the gate electrode, the source layer being formed in the semiconductor layer; and a drain layer arranged in other side of the gate electrode, the drain layer being formed in the semiconductor layer.

Accordingly, it is possible to arrange the channel on the film formation face, the film formation face being film-formed with epitaxial-growth, in addition to allowing the side wall of the semiconductor layer to have the channel. For this reason, even in the case where the side wall of the semiconductor layer is caused to have the channel, damages due to dry etching can be prevented from reaching the channel, and defects can be prevented from occurring in the channel region, and therefore the increase of the interface state density and the degradation of mobility in the channel region can be suppressed. Consequently, in addition to securing the current drive capability, the integration degree of transistors can be improved, and stable and excellent electrical characteristics can be obtained.

Moreover, even in the case where the side wall of the semiconductor layer is caused to have the channel, the film thickness of the semiconductor layer, in which the channel is to be formed, can be controlled with epitaxial-growth, and thus it is possible to stably carry out the film-thickness control of the semiconductor layer while allowing the film thickness of the semiconductor layer to be thin-filmed.

Moreover, according to the semiconductor device concerning the invention, it is preferable that the semiconductor layer be arranged on an insulating layer.

Accordingly, the source/drain junction capacitance can be reduced while preventing latch-up, and it is possible to attain the lower-power consumption and speeding up and realize the lower-voltage driving easily.

Moreover, according to the semiconductor device concerning the invention, it is preferable that the semiconductor layer be a distortion semiconductor layer.

Accordingly, in addition to allowing the semiconductor layer to have distortion, it is possible to cause the film formation face provided on the side wall of the semiconductor layer to have the channel, and the mobility of the transistors can be improved while suppressing complication of the manufacturing process.

Moreover, according to the semiconductor device concerning the invention, it is preferable that the gate electrode be formed in both side walls of the semiconductor layer as to straddle on the semiconductor layer.

Accordingly, it is possible to drive the transistor from both sides of the semiconductor layer while allowing the film formation face provided on the side wall of the semiconductor layer to have the channel, and thus the current drive capability can be enhanced while improving the integration degree of transistors.

Moreover, according to the semiconductor device concerning the invention, it is preferable that the semiconductor layer be in the shape of a protrusion, a fin, a box seat, or a mesh.

Accordingly, while allowing the film formation face provided on the side wall of the semiconductor layer to have the channel by arranging the gate electrode as to straddle the semiconductor layer, it is possible to drive the transistor from both sides of the semiconductor layer. For this reason, the current drive capability can be enhanced while suppressing complication of the manufacturing process, and the integration degree of transistors can be improved.

Moreover, according to another aspect of the invention, a method for manufacturing semiconductor devices includes the steps of patterning a first semiconductor layer formed on an insulator thereby to expose a side wall of the first semiconductor layer; film-forming a second semiconductor layer on a side wall of the first semiconductor layer with epitaxial-growth; removing the first semiconductor layer from the insulator while leaving the second semiconductor layer on the insulator; forming a gate electrode on a film formation face of the second semiconductor layer; and forming in the second semiconductor layer a source layer arranged on one side of the gate electrode and a drain layer arranged on other side of the gate electrode.

Accordingly, it is possible to epitxial-grow the second semiconductor layer on the side wall of the first semiconductor layer and give a channel on the film formation face of the second semiconductor layer, which is film-formed on the side wall of the first semiconductor layer. For this reason, even in the case where the side wall of the second semiconductor layer is caused to have the channel, it is possible to prevent the damages due to dry etching from reaching the channel, and control the film thickness of the second semiconductor layer, in which the channel is to be formed, with epitaxial-growth. Consequently, it is possible to prevent defects from occurring in the channel region, and even in the case where the side wall of the second semiconductor layer is caused to have the channel, it is possible to stably carry out the film-thickness control of the second semiconductor layer while allowing the film thickness of the second semiconductor layer to be thin-filmed. Thus, in addition to securing the current drive capability, it is possible to improve the integration degree of transistors and obtain the stable and excellent electrical characteristics.

Moreover, it is preferable that the method for manufacturing semiconductor devices further include the step of; prior to film-forming the second semiconductor layer on the side wall of the first semiconductor layer, carrying out heat treatment to the first semiconductor layer formed on the insulator, thereby relaxing the first semiconductor layer.

Accordingly, by film-forming the second semiconductor layer on the first semiconductor layer, it is possible to cause the second semiconductor layer to have distortion, and thus the mobility of the transistors can be improved while suppressing complication of the manufacturing process.

Moreover, according to a still further aspect of the invention, a method for manufacturing semiconductor devices includes the steps of: film-forming a first semiconductor layer on a base semiconductor layer that is formed on an insulator with epitaxial-growth; patterning the base semiconductor layer and first semiconductor layer thereby to expose side walls of the base semiconductor layer and the first semiconductor layer; film-forming a second semiconductor layer on the side wall of the first semiconductor layer with epitaxial-growth; removing the first semiconductor layer from the insulator while leaving the second semiconductor layer on the insulator; forming a gate electrode on a film formation face of the second semiconductor layer; and forming in the second semiconductor layer a source layer arranged on one side of the gate electrode and a drain layer arranged on other side of the gate electrode.

Accordingly, it is possible to cause the base semiconductor layer to support the second semiconductor layer onto the insulator, and even in the case where the first semiconductor layer that served as the foundation for film-forming the second semiconductor layer on the side wall is removed, the second semiconductor layer can be prevented from falling down. For this reason, it is possible to thin-film the second semiconductor layer and cause the side wall of the second semiconductor layer to have the channel, and thus while securing the current drive capability, it is possible to improve the integration degree of transistors and obtain the stable and excellent electrical characteristics.

According to yet another aspect of the invention, it is preferable that the method for manufacturing semiconductor devices further include the step of thermal-oxidizing the base semiconductor layer after removing the first semiconductor layer.

Accordingly, it is possible to insulate the base semiconductor layer, which remains after the first semiconductor layer is removed. For this reason, even in the case where the gate electrode is extended onto the base semiconductor layer, it is possible to prevent the channel from being formed in the base semiconductor layer and cause the transistors to have stable and excellent electrical characteristics.

According to yet another aspect of the invention, a method for manufacturing semiconductor devices includes the steps of: film-forming a first semiconductor layer on a semiconductor substrate with epitaxial-growth; exposing a side wall of the first semiconductor layer by patterning the first semiconductor layer that is film-formed on the semiconductor substrate; film-forming a second semiconductor layer on the side wall of the first semiconductor layer with epitaxial-growth; removing the first semiconductor layer from the semiconductor substrate while leaving the second semiconductor layer on the insulator; forming a gate electrode on a film formation face of the second semiconductor layer; and forming in the second semiconductor layer a source layer arranged on one side of the gate electrode and a drain layer arranged on other side of the gate electrode.

Accordingly, even in the case where the semiconductor substrate is used as the base layer of the first semiconductor layer, it is possible to epitaxial-grow the second semiconductor layer on the side wall of the first semiconductor layer and give a channel on the film formation face of the second semiconductor layer, which is film-formed on the side wall of the first semiconductor layer. For this reason, even in the case where the side wall of the second semiconductor layer is caused to have the channel, it is possible, without using a SOI substrate, to prevent the damages due to dry etching from reaching the channel, and control with epitaxial-growth the film thickness of the second semiconductor layer, in which the channel is to be formed. Consequently, in addition to securing the current drive capability, the integration degree of transistors can be improved and allowing the transistors to have the stable and excellent electrical characteristics while suppressing the cost increase.

According to yet another aspect of the invention, a method for manufacturing semiconductor devices includes the steps of film-forming a first semiconductor layer on a semiconductor substrate with epitaxial-growth; exposing a side wall of the first semiconductor layer by forming a step in the first semiconductor layer, film-forming a second semiconductor layer with the etching rate lower than the first semiconductor layer on the side wall of the first semiconductor layer with epitaxial-growth; forming a supporting medium that supports the second semiconductor layer on the semiconductor substrate, the supporting medium being composed of material with the etching rate lower than the first semiconductor layer; forming an exposure portion that exposes a part of the first semiconductor layer; forming, in between the semiconductor substrate and second semiconductor layer, a cavity in which the first semiconductor layer is removed by selectively etching the first semiconductor layer through the exposure portion; forming a buried insulating layer that is buried in the cavity; forming a gate electrode on a film formation face of the second semiconductor layer; and forming in the second semiconductor layer a source layer arranged on one side of the gate electrode and a drain layer arranged on other side of the gate electrode.

Accordingly, the second semiconductor layer can be epitaxial-grown on the side wall of the first semiconductor layer, and while allowing the side wall, in which the film formation face is formed with epitaxial-growth, to have the channel, it is possible to secure the selection ratio at the time of etching between the second semiconductor layer and the first semiconductor layer. For this reason, the first semiconductor layer can be selectively etched while suppressing the etching of the second semiconductor layer, which is film-formed on the side wall of the first semiconductor layer, and the cavity portion can be formed under the second semiconductor layer which is film-formed on the side wall of the first semiconductor layer. Furthermore, by providing the supporting medium that supports the second semiconductor layer on the semiconductor substrate, it is possible to prevent the second semiconductor layer, which is film-formed on the side wall of the first semiconductor layer, from dropping off onto the semiconductor substrate even in the case where the cavity portion is formed under the second semiconductor layer. For this reason, it is possible to arrange on the insulating layer the second semiconductor layer that is film-formed on the side wall of the first semiconductor layer, while reducing the occurrence of defects in the second semiconductor layer, and thus the isolation between the second semiconductor layer and the semiconductor substrate can be attained without damaging the quality of the second semiconductor layer, and the channel region can be extended in the vertical direction relative to the semiconductor substrate. Consequently, the integration degree of SOI transistors can be improved in addition to securing the current drive capability, and the fin type transistors can be formed on the insulator without using a SOI substrate, thereby allowing the transistors to have the stable and excellent electrical characteristics while attaining the cost reduction.

According to yet another aspect of the invention, a method for manufacturing semiconductor devices includes the steps of: film-forming a first semiconductor layer on a semiconductor substrate with epitaxial-growth; film-forming a second semiconductor layer arranged in a part of the region on the first semiconductor layer with epitaxial-growth; film-forming with epitaxial-growth on a side wall of the second semiconductor layer a third semiconductor layer with the etching rate lower than the first semiconductor layer and second semiconductor layer; forming a supporting-medium that supports the third semiconductor layer on the semiconductor substrate, the supporting medium being composed of material with the etching rate lower than the first semiconductor layer and the second semiconductor layer; forming an exposure portion that exposes a part of the first semiconductor layer or second semiconductor layer; forming, in between the semiconductor substrate and third semiconductor layer, a cavity in which the first semiconductor layer and second semiconductor layer are removed by selectively etching the first semiconductor layer and second semiconductor layer through the exposure portion; forming a buried insulating layer that is buried in the cavity; forming a gate electrode on a film formation face of the third semiconductor layer, and forming in the third semiconductor layer a source layer arranged on one side of the gate electrode and a drain layer arranged on other side of the gate electrode.

Accordingly, the third semiconductor layer can be epitaxial-grown on the side wall of the second semiconductor layer, and while allowing the side wall, in which the film formation face is formed with epitaxial-growth, to have the channel, it is possible to secure the selection ratio at the time of etching between the first semiconductor layer, the second semiconductor layer, and third semiconductor layer. For this reason, the first semiconductor layer and second semiconductor layer can be selectively etched while suppressing the etching of the third semiconductor layer that is film-formed on the side wall of the second semiconductor layer, and the cavity portion can be formed under the third semiconductor layer that is film-formed on the side wall of the second semiconductor layer. Furthermore, by providing the supporting medium that supports the third semiconductor layer on the semiconductor substrate, it is possible to prevent the third semiconductor layer, which is film-formed on the side wall of the second semiconductor layer, from dropping off onto the semiconductor substrate even in the case where the cavity portion is formed under the third semiconductor layer. For this reason, it is possible to arrange on the insulating layer the third semiconductor layer, which is film-formed on the side wall of the second semiconductor layer, while reducing the occurrence of defects in the third semiconductor layer. Thus, the isolation between the third semiconductor layer and the semiconductor substrate can be attained without damaging the quality of the third semiconductor layer, and the channel region can be extended in the vertical direction relative to the semiconductor substrate. Consequently, the integration degree of SOI transistors can be improved in addition to securing the current drive capability, and the fin type transistors can be formed on the insulator without using the SOI substrate, thereby allowing the transistors to have the stable and excellent electrical characteristics while attaining the cost reduction.

Moreover, it is preferable that the method for manufacturing semiconductor devices further include the step of forming a wiring layer that is coupled to the source layer or the drain layer as to bite into the second semiconductor layer.

Accordingly, contact can be made on the side wall of the second semiconductor layer-even in the case where the wiring layer is formed on the second semiconductor layer. For this reason, even in the case where the second semiconductor layer is thin-filmed, the area of the contact can be increased while suppressing complication of the manufacturing process, thereby allowing the transistors to have stable and excellent electrical characteristics without degrading the integration degree of transistors.

### BRIEF DESCRIPTION OF THE DRAWINGS

The invention will be described with reference to the accompanying drawings, wherein like numbers refer to like elements.

FIG. 1 is a perspective view showing an outline configuration of a semiconductor device concerning a first embodiment of the invention.

FIG. 2 is a view showing a manufacturing method of a semiconductor device concerning a second embodiment of the invention.

FIG. 3 is a view showing the manufacturing method of the semiconductor device concerning the second embodiment of the invention.

FIG. 4 is a view showing the manufacturing method of the semiconductor device concerning the second embodiment of the invention.

FIG. 5 is a view showing the manufacturing method of the semiconductor device concerning the second embodiment of the invention.

FIG. 6 is a view showing the manufacturing method of the semiconductor device concerning the second embodiment of the invention.

FIG. 7 is a view showing the manufacturing method of the semiconductor device concerning the second embodiment of the invention.

FIG. 8 is a view showing the manufacturing method of the semiconductor device concerning the second embodiment of the invention.

FIG. 9 is a view showing the manufacturing method of the semiconductor device concerning the second embodiment of the invention.

FIG. 10 is a view showing a manufacturing method of a semiconductor device concerning a third embodiment of the invention.

FIG. 11 is a view showing the manufacturing method of the semiconductor device concerning the third embodiment of the invention.

FIG. 12 is a view showing the manufacturing method of the semiconductor device concerning the third embodiment of the invention.

FIG. 13 is a view showing the manufacturing method of the semiconductor device concerning the third embodiment of the invention.

FIG. 14 is a view showing the manufacturing method of the semiconductor device concerning the third embodiment of the invention.

FIG. 15 is a view showing the manufacturing method of the semiconductor device concerning the third embodiment of the invention.

FIG. 16 is a view showing the manufacturing method of the semiconductor device concerning the third embodiment of the invention.

FIG. 17 is a view showing the manufacturing method of the semiconductor device concerning the third embodiment of the invention.

FIG. 18 is a view showing the manufacturing method of the semiconductor device concerning the third embodiment of the invention.

FIG. 19 is a view showing the manufacturing method of the semiconductor device concerning the third embodiment of the invention.

FIG. 20 is a view showing the manufacturing method of the semiconductor device concerning the third embodiment of the invention.

FIG. 21 is a view showing the manufacturing method of the semiconductor device concerning the third embodiment of the invention.

FIG. 22 is a view showing a manufacturing method of a semiconductor device concerning a fourth embodiment of the invention.

FIG. 23 is a view showing the manufacturing method of the semiconductor device concerning the fourth embodiment of the invention.

FIG. 24 is a view showing the manufacturing method of the semiconductor device concerning the fourth embodiment of the invention.

FIG. 25 is a view showing the manufacturing method of the semiconductor device concerning the fourth embodiment of the invention.

FIG. 26 is a view showing the manufacturing method of the semiconductor device concerning the fourth embodiment of the invention.

FIG. 27 is a view showing the manufacturing method of the semiconductor device concerning the fourth embodiment of the invention.

FIG. 28 is a view showing the manufacturing method of the semiconductor device concerning the fourth embodiment of the invention.

### DESCRIPTION OF THE EMBODIMENTS

Hereinafter, semiconductor devices and methods for manufacturing the same concerning embodiments of the invention will be described with reference to the accompanying drawings.

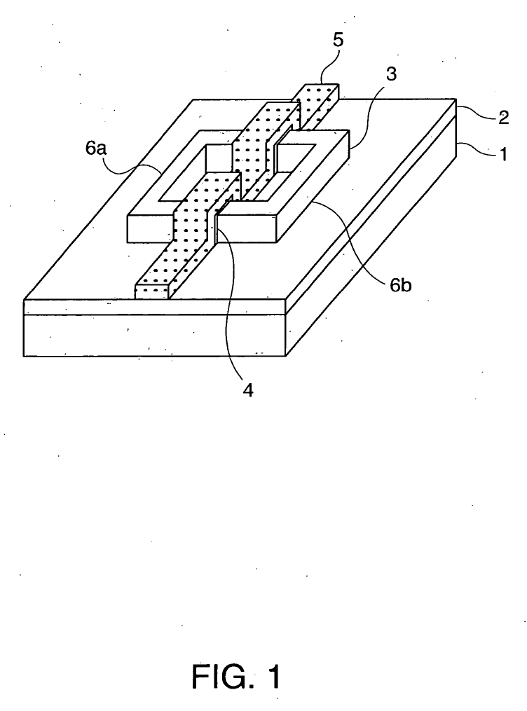

FIG. 1 is a perspective view showing an outline configuration of a semiconductor device concerning a first embodiment of the invention.

In FIG. 1, an insulating layer 2 is formed on a semiconductor substrate 1, and a semiconductor layer 3 is formed on an insulating layer 2 with epitaxial-growth. Here, the semiconductor layer 3 is epitaxial-grown as to have a film formation face on a side wall, and the semiconductor layer 3 is arranged as to stand steeply on the insulating layer 2. In addition, as the method for arranging the semiconductor layer 3 on the insulating layer 2, the shape of a protrusion, a fin, a box seat, or a mesh may be used, for example. Moreover, the quality of material for the semiconductor substrate 1 and semiconductor layer 3 may be selected from Si, Ge, SiGe, SiGeC, SiC, SiSn, PbS, GaAs, InP, GaP, GaN, or ZnSe, for example. Moreover, for example, FSG (fluoride silicate glass) film or a silicon nitride film, other than a silicon oxide film, may be used. Moreover, as the insulating layer 2, PSG film, BPSG film, the PAE (poly aryleneether) system film, HSQ (hydrogen silsesquioxane) system film, MSQ (methyl silsesquioxane) system film, PCB system film, CF system film, SiOC system film, a low-k organic film such as SiOF system film, or porous film thereof, other than the SOG (Spin On Glass) film, may be used as the quality of material of the insulating layer 2. Moreover, the semiconductor layer 3 may have distortion.

Then, on the side wall of the semiconductor layer 3, a gate electrode 5 is arranged through a gate insulating layer 4. Furthermore, source/drain layers 6a and 6b arranged on the sides of the gate electrode 5, respectively, are formed in the semiconductor layer 3.

Accordingly, it is possible to arrange a channel on the film formation face, which is film-formed with epitaxial-growth, in addition to allowing the side wall of the semiconductor layer 3 to have the channel. For this reason, even in the case where the side wall of the semiconductor layer 3 is caused to have the channel, damages due to dry etching can be prevented from reaching the channel, and defects can be prevented from occurring in the channel region, and therefore the increase of the interface state density and the degradation of mobility in the channel region can be suppressed. Consequently, in addition to securing the current drive capability, the integration degree of transistors can be improved, and the stable and excellent electrical characteristics can be obtained. Moreover, even in the case where the side wall of the semiconductor layer 3 is caused to have the channel, the film thickness of the semiconductor layer 3, in which a channel is to be formed, can be controlled with epitaxial-growth, and the film-thickness control of the semiconductor layer 3 can be carried out stably while allowing the film thickness of the semiconductor layer 3 to be thin-filmed.

Here, in the case where the gate electrode 5 is arranged on the side wall of the semiconductor layer 3, the gate electrode 5 can be formed on both sides of the walls of the semiconductor layer 3 as to straddle on the semiconductor layer 3. Accordingly, it is possible to drive the transistor from both sides of the semiconductor layer 3 while allowing the film formation face provided on the side wall of the semiconductor layer 3 to have the channel, and thus the current drive capability can be enhanced while improving the integration degree of transistors.

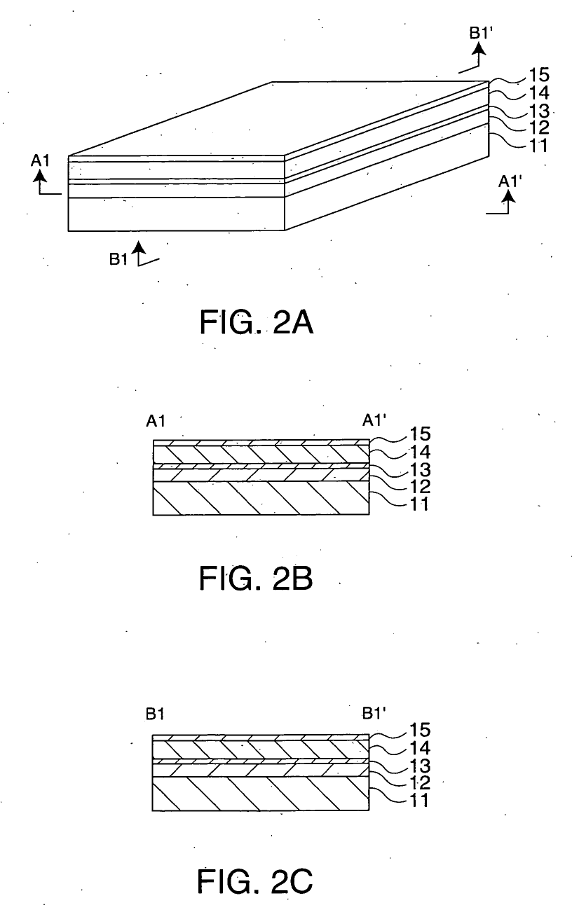

FIG. 2A through FIG. 9A are perspective views showing the manufacturing method of a semiconductor device concerning a second embodiment of the invention, FIG. 2B through FIG. 9B are sectional views cut at A1-A1′ to A8-A8′ lines of FIG. 2A-FIG. 9A, respectively. FIG. 2C through FIG. 9C are sectional views cut at B1-B1′ to B8-B8′ lines of FIG. 2A through FIG. 9A, respectively.

In FIG. 2, an insulating layer 12 is formed on a semiconductor substrate 11, and a base semiconductor layer 13 is formed on the insulating layer 12. Then, a first semiconductor layer 14 is formed on the base semiconductor layer 13 by carrying out epitaxial-growth. Then, an insulating film 15 is formed on the first semiconductor layer 14 with a method, such as CVD. In addition, as the quality of material of the semiconductor substrate 11, the base semiconductor layer 13, and the first semiconductor layer 14, for example, combinations selected from Si, Ge, SiGe, SiGeC, SiC, SiSn, PbS, GaAs, InP, GaP and GaN, or ZnSe etc. may be used. Moreover, as the quality of material of the insulating layer 12 and insulating film 15, for example, silicon oxide film etc. may be used.

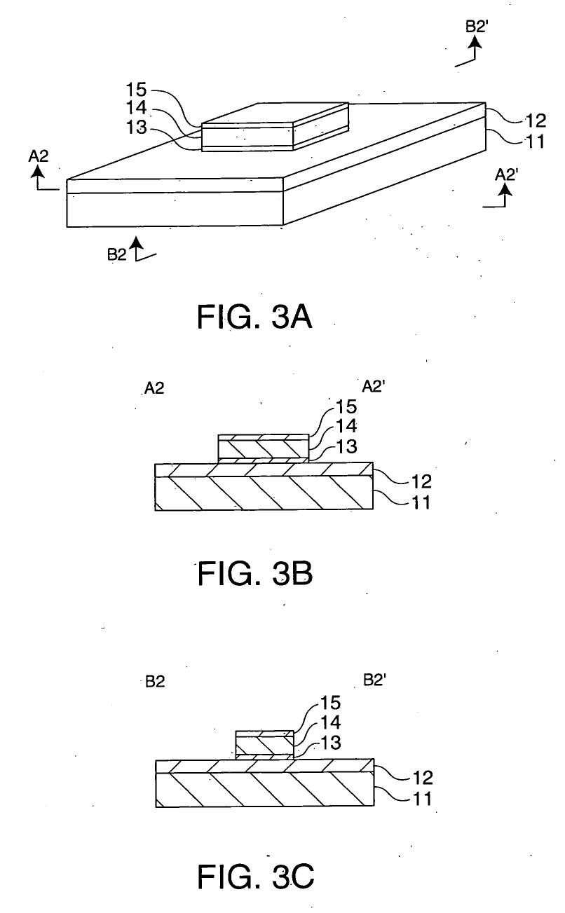

Next, as shown in FIG. 3, the side walls of the first semiconductor layer 14 and base semiconductor layer 13 are exposed by patterning the insulating film 15, the first semiconductor layer 14, and the base-semiconductor layer 13 using a photo lithography technique and an etching technique.

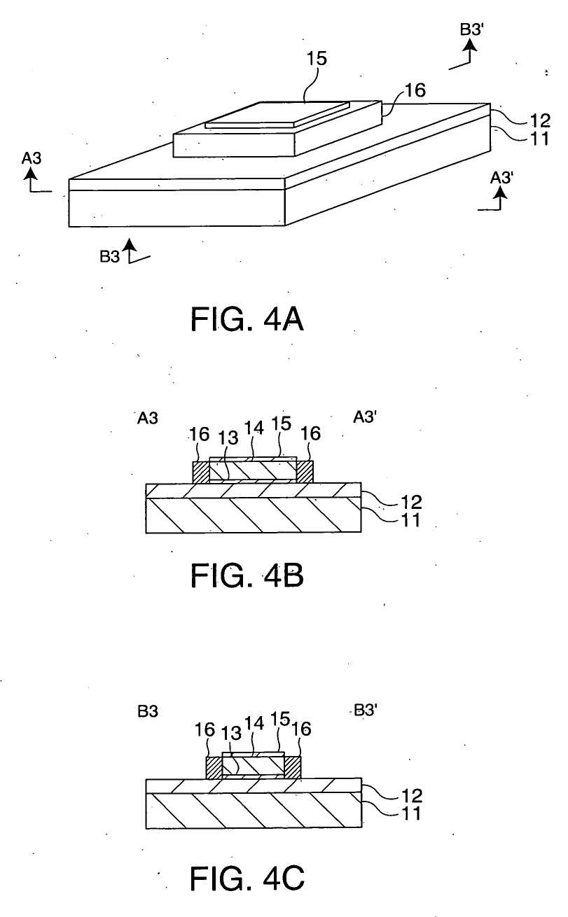

Next, as shown in FIG. 4, a second semiconductor layer 16 is selectively epitaxial-grown using the insulating film 15 as a mask, thereby selectively film-forming the second semiconductor layer 16 on the side walls of the first semiconductor layer 14 and base semiconductor layer 13. Here, because in the selective epitaxial-growth of the second semiconductor layer 16 the second semiconductor layer 16 is not film-formed on the insulating layer 12 and insulating film 15, the second semiconductor layer 16 can be formed only on the side walls of the first semiconductor layer 14 and base semiconductor layer 13. In addition, the quality of material of the second semiconductor layer 16 may be selected from, for example, Si, Ge, SiGe, SiC, SiSn, PbS, GaAs, InP, GaP and GaN, or ZnSe etc. In particular, when the second semiconductor layer 16 is Si, it is preferable to use SiGe as the first semiconductor layer 14 and Si as the base semiconductor layer 13. Accordingly, the selection ratio between the first semiconductor layer 14 and second semiconductor layer 16 can be secured while allowing the lattice matching between the first semiconductor layer 14 and second semiconductor layer 16, and thus it is possible to form the second semiconductor layer 16 with excellent crystal quality on the side wall of the first semiconductor layer 14.

Moreover, by forming the base semiconductor layer 13 on the insulating layer 12, the second semiconductor layer 16 can be supported on the insulator 12 with the base semiconductor layer 13. For this reason, the second semiconductor layer 16 can be prevented from falling down even in the case where the first semiconductor layer 14, which served as the foundation for film-forming the second semiconductor layer 16 on the side wall, is removed.

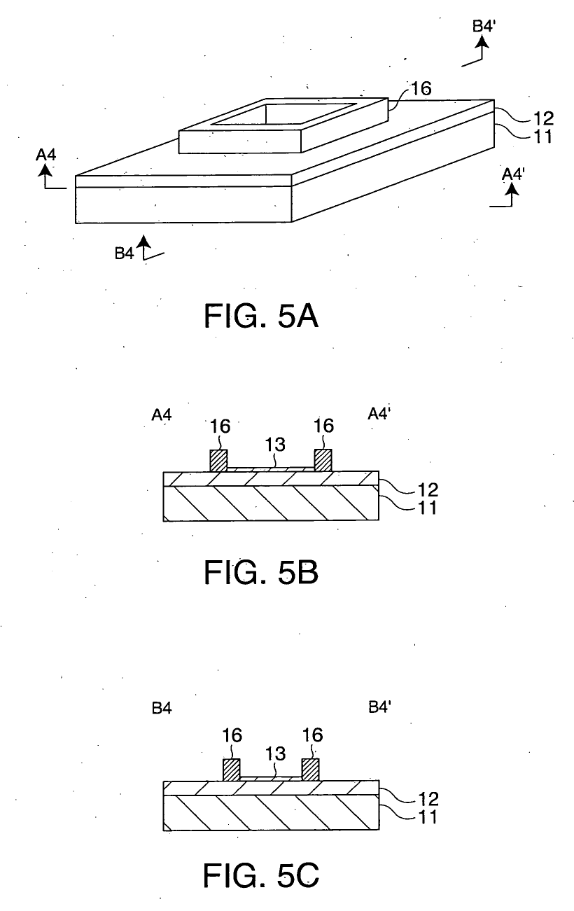

Next, as shown in FIG. 5, after removing the insulating film 15 on the first semiconductor layer 14, the first semiconductor layer 14 is etch-removed contacting the etching gas or etchant with the first semiconductor layer 14. In addition, it is preferable to use a fluoride nitric acid (a mixed solution of hydrofluoric acid, nitric acid, and water) as the etchant for the first semiconductor layer 14 when the base semiconductor layer 13 and second semiconductor layer 16 are made of Si, and the first semiconductor layer 14 is made of SiGe. Accordingly, the selection ratio between Si and SiGe on the order of 1:100-1000 can be obtained, and the first semiconductor layer 14 can be removed while suppressing the over-etching of the base semiconductor layer 13 and second semiconductor layer 16. Moreover, fluoride nitric acid hydrogen peroxide, ammonia hydrogen peroxide, or fluoride acetic-acid hydrogen peroxide may be used as the etchant for the first semiconductor layer 14.

Moreover, by patterning the first semiconductor layer 14 so that the second semiconductor layer 16 may remain on the insulator 12 in the shape of a box seat or a mesh when the first semiconductor layer 14 is removed, the second semiconductor layer 16 can be prevented from falling down even in the case where the second semiconductor layer 16 is thin-filmed.

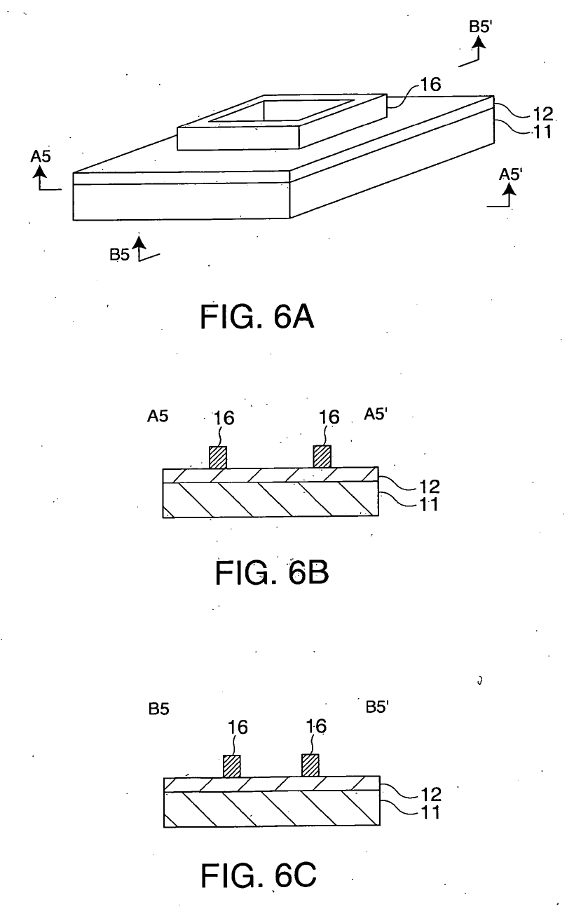

Next, as shown in FIG. 6, the base semiconductor layer 13 is removed carrying out anisotropic etching of the base semiconductor layer 13. In addition, in order to protect the second semiconductor layer 16 from the damages due to the anisotropic etching, the anisotropic etching of the base semiconductor layer 13 may be carried out after carrying out the thermal oxidation of the surface of the second semiconductor layer 16. Moreover, as the method for removing the base semiconductor layer 13, the base semiconductor layer 13 may be insulated by carrying out the thermal oxidation of the base semiconductor layer 13. In addition, the base semiconductor layer 13 may be left on the insulator 12 as it is without removing the base semiconductor layer 13.

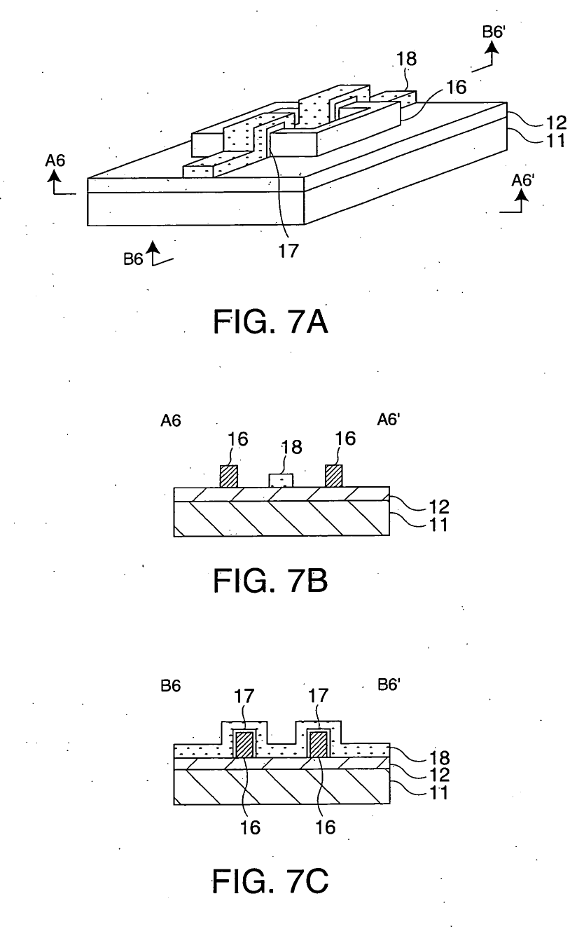

Next, as shown in FIG. 7, a gate insulating film 17 is formed in the surface of the second semiconductor layer 16 by carrying out the thermal oxidation of the surface of the second semiconductor layer 16. Then, a polycrystal silicon layer is formed on the second semiconductor layer 16, in which the gate insulating film 17 is formed, with a method such as CVD. Then, by patterning the polycrystal silicon layer using a photo lithography technique and etching technique, the gate electrode 18 arranged as to straddle on the second semiconductor layer 16 through the side wall of the second semiconductor layer 16 is formed on the insulating layer 12.

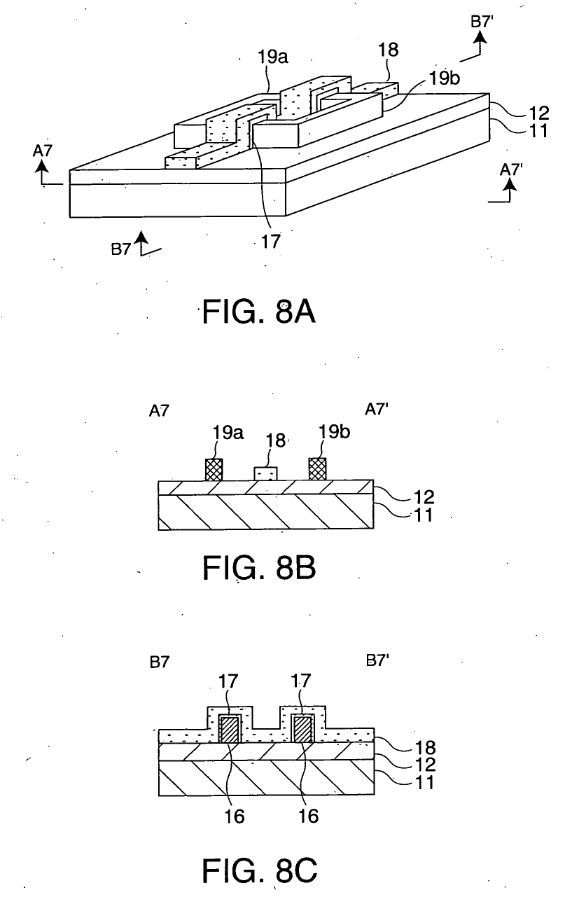

Next, as shown in FIG. 8, by ion implanting impurities, such as As, P, and B, in the second semiconductor layer 16 using the gate electrode 18 as a mask, source/drain layers 19a and 19b arranged on the sides of the gate electrode 18, respectively, are formed in the second semiconductor layer 16.

Accordingly, it is possible to epitaxial-grow the second semiconductor layer 16 on the side wall of the first semiconductor layer 14 and give a channel on the film formation face of the second semiconductor layer 16, which is film-formed on the side wall of the first semiconductor layer 14. For this reason, even in the case where the side wall of the second semiconductor layer 16 is caused to have the channel, it is possible to prevent damages due to the dry etching from reaching the channel, and control the film thickness of the second semiconductor layer 16, in which the channel is to be formed, with epitaxial-growth. Consequently, it is possible to prevent defects from occurring in the channel region, and even in the case where the side wall of the second semiconductor layer 16 is caused to have the channel, it is possible to stably carry out the film-thickness control of the second semiconductor layer 16 while allowing the film thickness of the second semiconductor layer 16 to be thin-filmed. Thus, in addition to securing the current drive capability, it is possible to improve the integration degree of transistors and obtain the stable and excellent electrical characteristics.

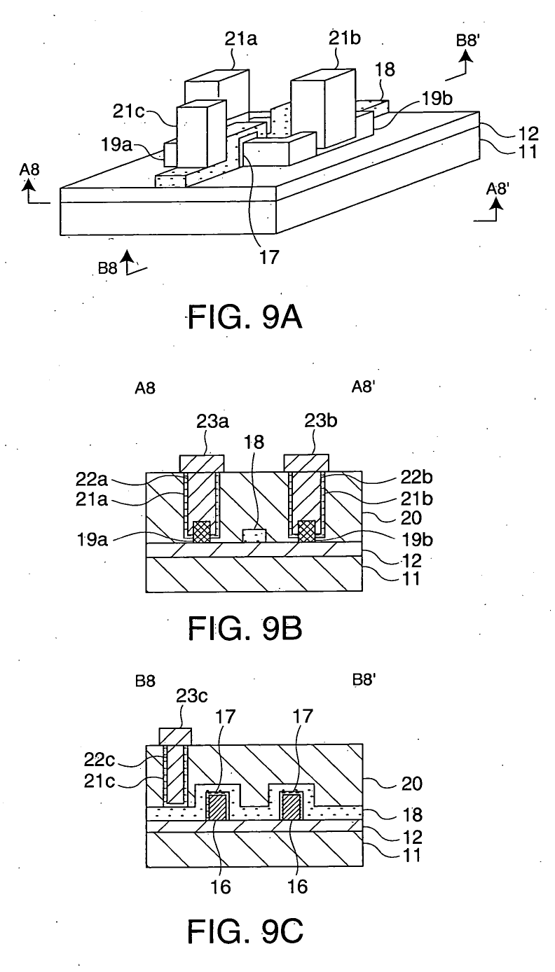

Next, as shown in FIG. 9, an interlayer insulating film 20 is formed on the second semiconductor layer 16 with a method such as plasma CVD. Then, for example, by polishing the surface of the interlayer insulating film 20 using CMP, the surface of the interlayer insulating film 20 is planarized. Then, by patterning the interlayer insulating film 20 using a photo lithography technique and etching technique, openings for exposing the source/drain layers 19a and 19b as well as the gate electrode 18 are formed in the interlayer insulating film 20. Here, when forming in the interlayer insulating film 20 the openings for exposing the source/drain layers 19a and 19b, the size of the openings can be set so that the openings may extrude in the film thickness direction of the second semiconductor layer 16. Then, when carrying out etching for forming the openings in the interlayer insulating film 20, the interlayer insulating film 20 can be over-etched so that the interlayer insulating film 20 in the portion, which is in contact with the side wall of the second semiconductor layer 16, may be dug down.

Then, Ti/TiN is sequentially film-formed using a method such as sputtering, thereby forming a barrier metal film in the surface of the interlayer insulating film 20, in which the openings are provided. Then, for example, a tungsten film is formed on the barrier metal film by carrying out CVD using WF₆/SiH₄/H₂/Ar system gas, and by polishing the barrier metal film and tungsten film using CMP, tungsten plugs 22a through 22c coupled to the source/drain layers 19a and 19b as well as the gate electrode 18, respectively, through the barrier metal film 21a through 21c, respectively, are buried in the interlayer insulating film 20. Then, for example, by sputtering TiN/Al—Cu/Ti/TiN sequentially onto the interlayer insulating film 20 and patterning a multi-layered structure composed of TiN/Al—Cu/Ti/TiN using a photo lithography technique and etching technique, wiring layers 23a through 23c coupled to the tungsten plugs 22a through 22c, respectively, are formed on the interlayer insulating film 20.

Accordingly, contact can be made on the side wall of the second semiconductor layer 16 even in the case where the wiring layers 23a through 23c are formed on the second semiconductor layer 16. For this reason, even in the case where the second semiconductor layer 16 is thin-filmed, the contact area can be increased while suppressing complication of the manufacturing process, thereby allowing the transistors to have stable and excellent electrical characteristics without degrading the integration degree of transistors.

In addition, although in the above-described embodiment a method for forming the first semiconductor layer 14 on the base semiconductor layer 13 formed on the insulating layer 12 has been described, the semiconductor substrate 11 may be used in which the insulating layer 12 is formed on the semiconductor substrate 11 and the first semiconductor layer 14 is formed on the insulating layer 12 in advance. In this case, the base semiconductor layer 13 may be omitted.

Moreover, prior to film-forming the second semiconductor layer 16 on the side wall of the first semiconductor layer 14, the first semiconductor layer 14 may be relaxed carrying out heat treatment of the first semiconductor layer 14 formed on the insulator 12. Accordingly, by film-forming the second semiconductor layer 16 on the first semiconductor layer 14, it is possible to cause the second semiconductor layer 16 to have distortion, and thus the mobility of transistors can be improved while suppressing complication of the manufacturing process.

Moreover, although in the above-described embodiment a method for forming SOI transistors in the second semiconductor layer 16 has been described, this may be applied to the method for forming TFT (Thin Film Transistor).

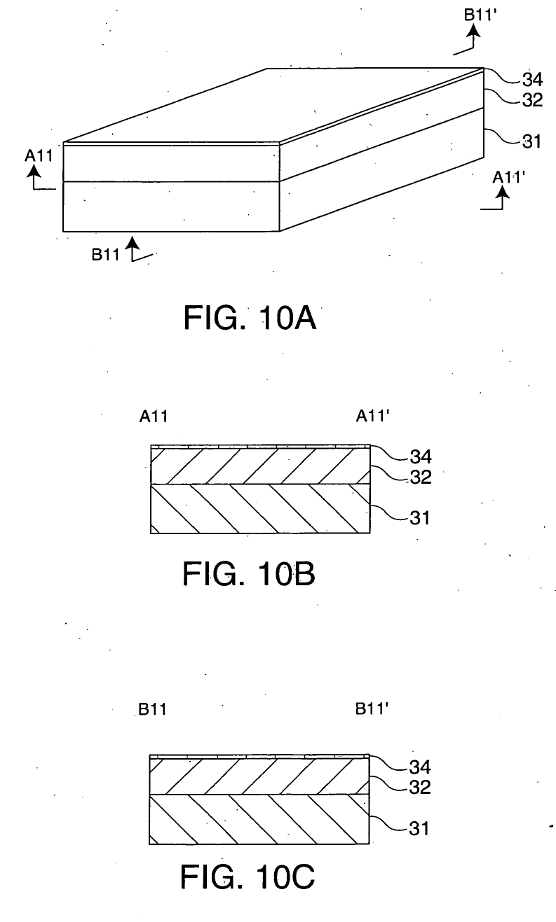

FIG. 10A through FIG. 21A are perspective views showing the manufacturing method of a semiconductor device concerning a third embodiment of the invention, FIG. 10B through FIG. 21B are sectional views cut at A11-A11′ to A21-A21′ lines of FIG. 10A through FIG. 21A, respectively, and FIG. 10C through FIG. 21C are sectional views cut at B11-B11′ to B21-B21′ lines of FIG. 10A through FIG. 21A, respectively.

In FIG. 10, a first semiconductor layer 32 is film-formed on a semiconductor substrate 31 with epitaxial-growth. Then, an insulating film 34 is formed on the first semiconductor layer 32 with a method such as CVD.

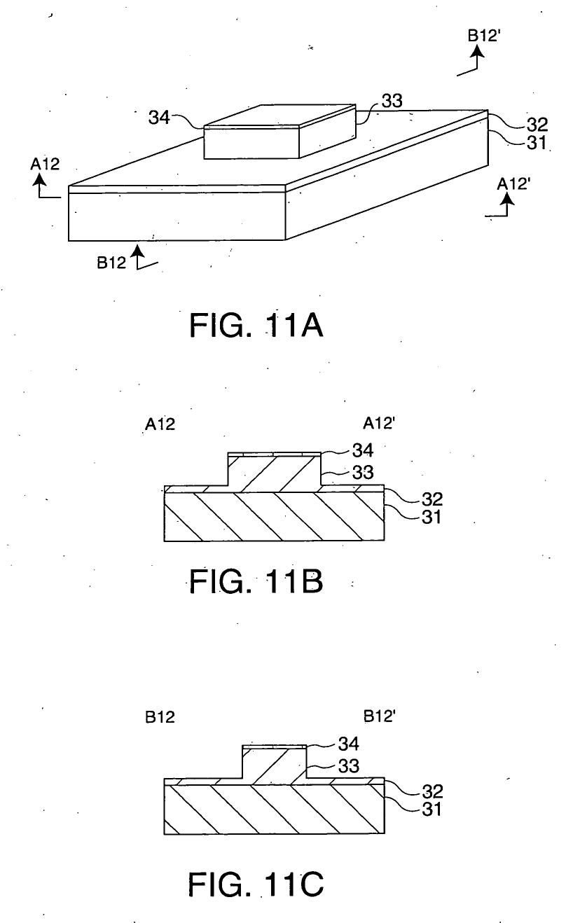

Next, as shown in FIG. 11, a protrusion 33 that exposes the side wall of the first semiconductor layer 32 is formed in the first semiconductor layer 32 by patterning an insulating film 34 and the first semiconductor layer 32 using a photo lithography technique and etching technique. Here, when forming, on the first semiconductor layer 32, the protrusion 33 that exposes the side wall of the first semiconductor layer 32, etching of the first semiconductor layer 32 is stopped in the intermediate depth so that the first semiconductor layer 32 may remain on the semiconductor substrate 31 around the protrusion 33.

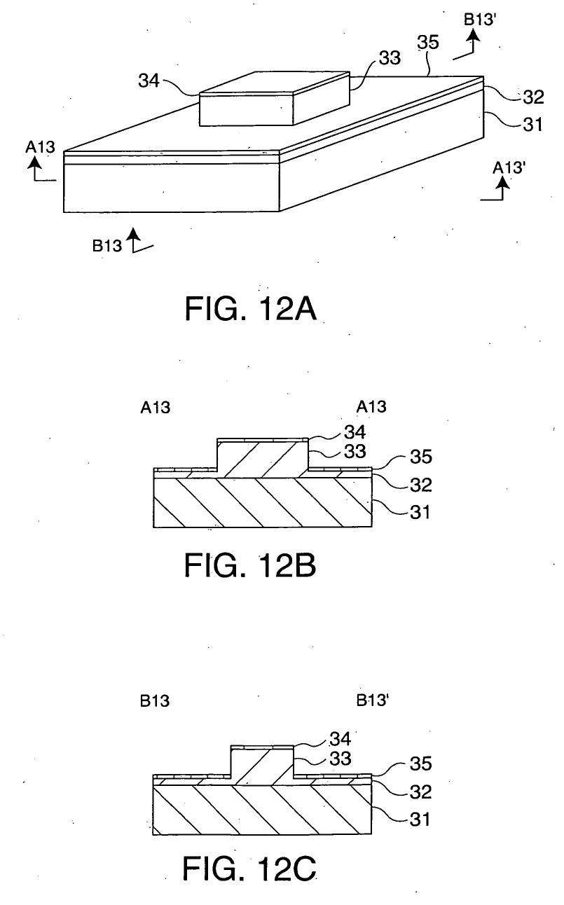

Next, as shown in FIG. 12, for example, by using an anisotropic film formation method such as sputter, an insulating film 35 is film-formed on the first semiconductor layer 32 around the protrusion 33 such that the insulating film 35 may not adhere to the side wall of the protrusion 33. In addition, at the time of film-forming the insulating film 35 on the first semiconductor layer 32 around the protrusion 33, if the insulating film 35 adheres to the side wall of the protrusion 33, then isotropic etching such as wet etching may be carried out, thereby removing the insulating film 35 adhered to the side wall of the protrusion 33 while leaving the insulating film 35 on the first semiconductor layer 32. Alternatively, after forming a nitride film on the whole surface with a CVD method, anisotropic etching is carried out to the whole surface, thereby leaving the nitride film only on the side face of the second semiconductor layer 33, and thereafter thermal oxidation process is carried out. Subsequently, if this side wall nitride film is removed, as shown in FIG. 12, then the oxidized insulating film is formed in the whole surface except the side wall of the second semiconductor layer 33.

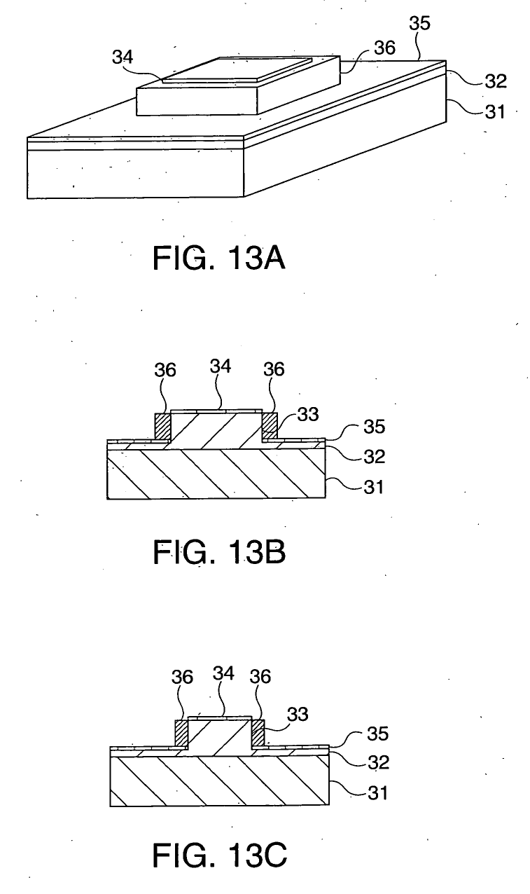

Next, as shown in FIG. 13, a second semiconductor layer 36 is film-formed, with selective epitaxial-growth, on the side wall of the protrusion 33 provided in the first semiconductor layer 32. Here, because in the selective epitaxial-growth of the second semiconductor layer 36, the second semiconductor layer 36 is not film-formed on the insulating films 34 and 35, the second semiconductor layer 36 can be formed only on the side wall of the protrusion 33 provided in the first semiconductor layer 32.

In addition, for the first semiconductor layer 32, the quality of material with etching rate higher than the semiconductor substrate 31 and second semiconductor layer 36 may be used, and for the quality of material of the semiconductor substrate 31, the first semiconductor layer 32; and the semiconductor layers 36, for example, combinations selected from Si, Ge, SiGe, SiC, SiSn, PbS, GaAs, InP, GaP and GaN, or ZnSe may be used. In particular, in the case where the semiconductor substrate 31 is Si, it is preferable to use SiGe as the first semiconductor layer 32 and Si as the second semiconductor layer 36. Accordingly, the selection ratio between the first semiconductor layer 32 and second semiconductor layer 36 can be secured while allowing the lattice matching between the first semiconductor layer 32 and second semiconductor layer 36. In addition, a polycrystal semiconductor layer, an amorphous semiconductor layer or a porous semiconductor layer, other than the single crystal semiconductor-layer, may be also used as the first semiconductor layer 32. Moreover, a metal oxide film such as γ-aluminum oxide, which can be film-formed from a single crystal semiconductor layer with epitaxial-growth, may be used in place of the first semiconductor layer 32.

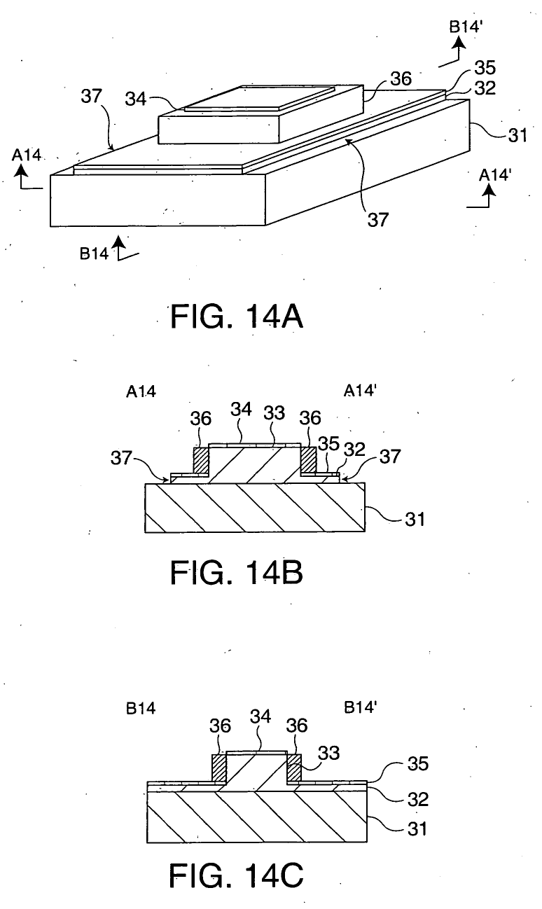

Next, as shown in FIG. 14, an exposed surface 37 that exposes the side wall of the first semiconductor layer 32 is formed patterning the insulating film 35 and first semiconductor layer 32 using a photo lithography technique and etching technique. In addition, in patterning the first semiconductor layer 32, in order to protect the second semiconductor layer 36 an oxide film may be formed in the surface of the second semiconductor layer 36 using a method such as the thermal oxidation or CVD of the second semiconductor layer 36. Moreover, at the time of forming the exposed surface 37 that exposes the side wall of the first semiconductor layer 32, the etching may be stopped on the surface of the semiconductor substrate 31, or the semiconductor substrate 31 may be over etched to form a recess in the semiconductor substrate 31.

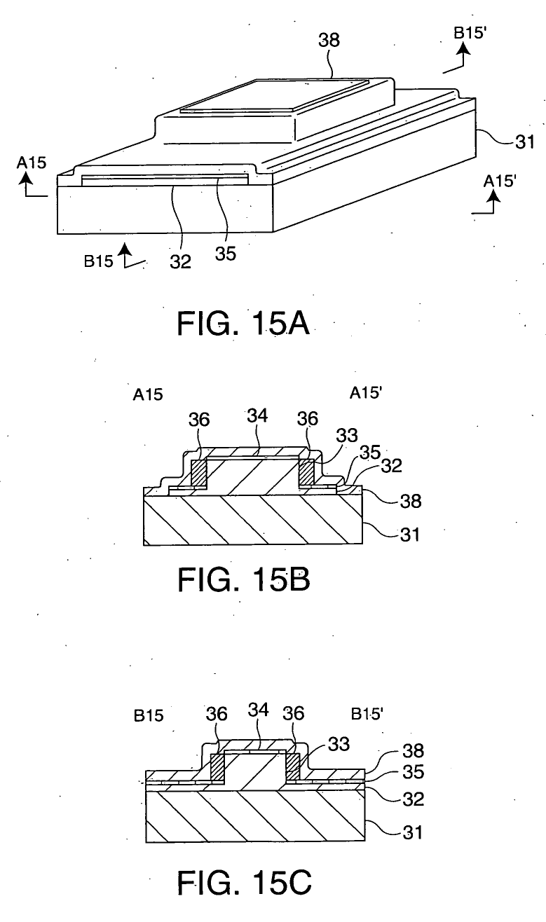

Next, as shown in FIG. 15, a supporting medium 38, which is arranged such that the exposed surface 37 may be covered, is film-formed in the whole surface of the semiconductor substrate 31 with a method such as CVD. In addition, as the quality of material of the supporting medium 38, for example, an insulator, such as silicon oxide film and silicon nitride film may be used. Alternatively, semiconductors, such as polycrystal silicon and single crystal silicon may be used as the quality of material of the supporting medium 38.

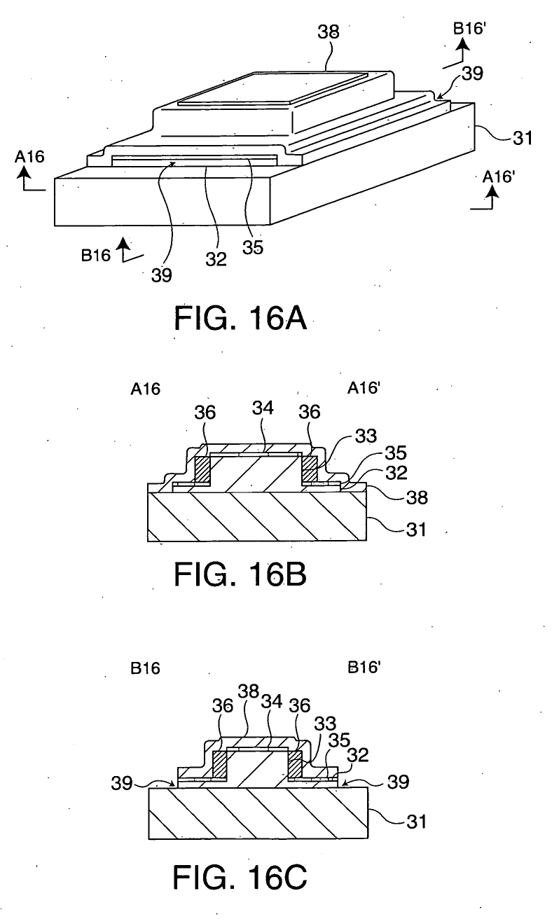

Next, as shown in FIG. 16, an exposed surface 39 for exposing a part of the first semiconductor layer 32 is formed patterning the supporting medium 38 and first semiconductor layer 32 using a photo lithography technique and etching technique. Moreover, in the case where a part of the first semiconductor layer 32 is exposed, the etching may be stopped on the surface of the first semiconductor substrate 32, or the semiconductor substrate 32 may be over etched to form the recess in the semiconductor substrate 32. Alternatively, the surface of the semiconductor substrate 31 may be exposed penetrating through the first semiconductor layer 32. Here, by stopping the etching of the first semiconductor layer 32 halfway, the surface of the semiconductor substrate 31 may be prevented from being exposed. For this reason, in etch-removing the first semiconductor layer 32, it is possible to reduce the time for the semiconductor substrate 31 to be exposed to the etchant or etching gas, and the over-etching of the semiconductor substrate 31 can be suppressed.

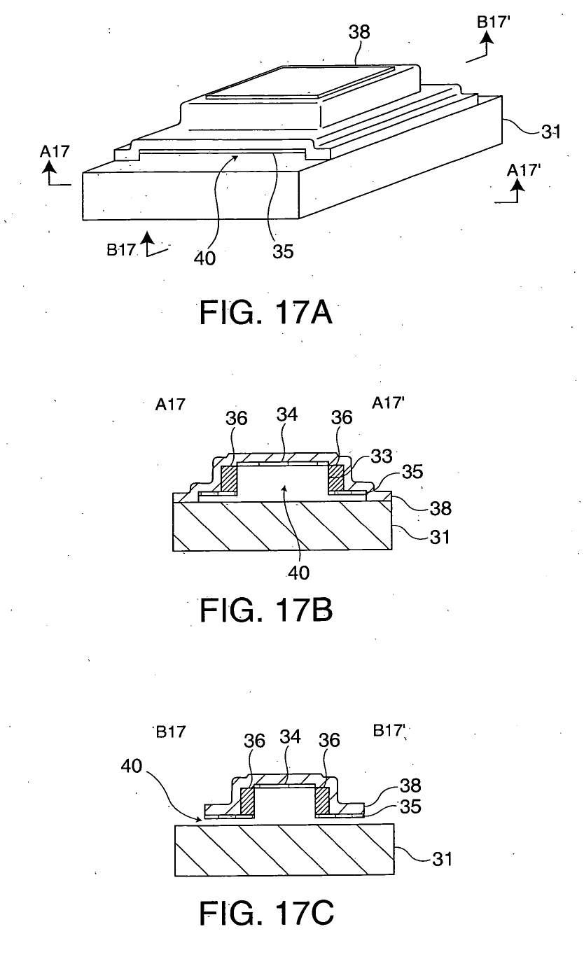

Next, as shown in FIG. 17, by contacting the etching gas or etchant with the first semiconductor layer 32 through the exposed surface 39, the first semiconductor layer 32 is etch-removed to form a cavity 40 in between the semiconductor substrate 31 and second semiconductor layer 36.

Here, by forming in the first semiconductor layer 32 the protrusion 33 that exposes the side wall of the first semiconductor layer 32, it is possible to epitaxial-grow the second semiconductor layer 36 on the side wall of the first semiconductor layer 32, and the selection ratio at the time of etching between the second semiconductor layer 36 and first semiconductor layer 32 can be secured in addition to allowing the side wall of the second semiconductor layer 36 to have the film formation face. For this reason, the first semiconductor layer 32 can be selectively etched while suppressing the etching of the second semiconductor layer 36 that is film-formed on the side wall of the first semiconductor layer 32, and the cavity 40 can be formed under the second semiconductor layer 36 that has the film formation surface on the side wall.

Furthermore, by preparing the supporting medium 38 that supports the second semiconductor layer 36 on the semiconductor substrate 31, it is possible to prevent the second semiconductor layer 36, which is film-formed on the side wall of the first semiconductor layer 32, from dropping off even in the case where the cavity 40 is formed under the second semiconductor layer 36. For this reason, it is possible to arrange on the insulating layer the second semiconductor layer 36 that is film-formed on the side wall of the first semiconductor layer 32, while reducing the occurrence of defects in the second semiconductor layer 36, and thus the isolation between the second semiconductor layer 36 and semiconductor substrate 31 can be attained without damaging the quality of the second semiconductor layer 36. Moreover, the surface area of the second semiconductor layer 36, which can be formed on the insulating layer, can be enlarged without increasing the chip size, and the second semiconductor layer 36 with excellent crystal quality can be formed on the insulating layer at low cost.

Furthermore, by forming the exposed surface 39 independently from the exposed surface 37, it is possible to contact the etching gas or etchant with the first semiconductor layer 32 under the second semiconductor layer 36 even in the case where the supporting medium 38, which supports the second semiconductor layer 36 on the semiconductor substrate 31, is formed. For this reason, the isolation between the second semiconductor layers 36, which is film-formed on the side wall of the first semiconductor layer 32, and the semiconductor substrates 31, can be attained without damaging the quality of the second semiconductor layer 36.

In addition, it is preferable to use a fluoride nitric acid as the etchant for the first semiconductor layer 32 if the semiconductor substrate 31 and second semiconductor layer 36 are made of Si and the first semiconductor layer 32 is made of SiGe. Accordingly, the selection ratio between Si and SiGe on the order of 1:100-1000 can be obtained, and the first semiconductor layer 32 can be removed while suppressing the over-etching of the semiconductor substrate 31 and second semiconductor layer 36.

Moreover, prior to etch-removing the first semiconductor layer 32, the first semiconductor layer 32 may be made porous with a method, such as anodic oxidation, and the first semiconductor layer 32 may be made amorphous by carrying out ion implantation in the first semiconductor layer 32. Accordingly, the etching rate of the first semiconductor layer 32 can be increased, and the etching area of the first semiconductor layer 32 can be enlarged.

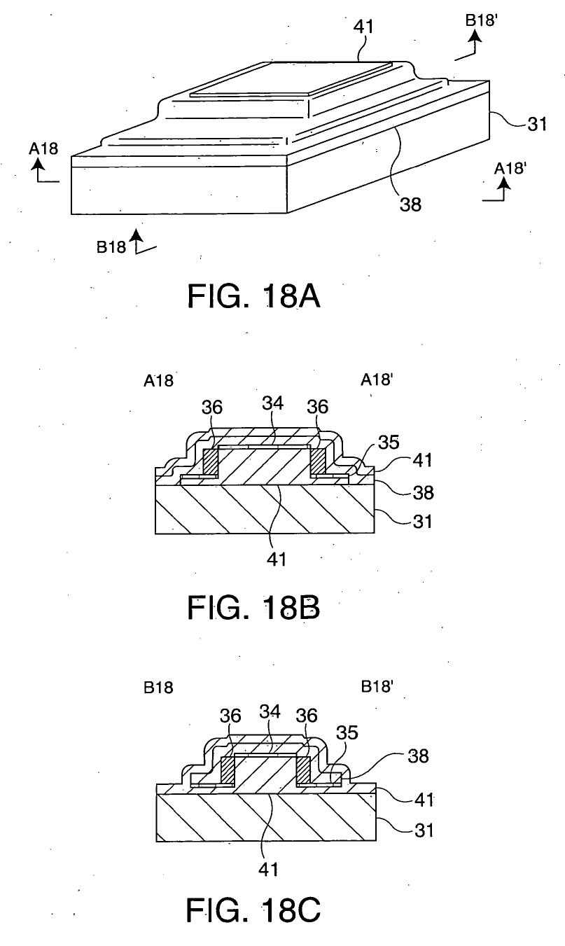

Next, as shown in FIG. 18, with a method, such as CVD, an insulating film 41 is deposited in the whole surface of the semiconductor substrate 31 so that the cavity 40 under the second semiconductor layer 36 may be buried.

Accordingly, the insulating film 41 can be formed under the second semiconductor layer 36, which is film-formed on the side wall of the first semiconductor layer 32, and the second semiconductor layer 36, which has on the side wall the film formation face formed with epitaxial-growth, can be arranged on the insulating film 41. For this reason, in addition to allowing the second semiconductor layer 36 to be thin-filmed without using a SOI substrate, it is possible to stand and arrange the second semiconductor layer 36 on the insulating film 41, and it is possible to form on the insulating film 41 the second semiconductor layer 36 with an excellent crystal quality at low cost, while allowing the surface area of the second semiconductor layer 36 to be enlarged easily.

Moreover, as the insulating film 41, for example, FSG (fluoride silicate glass) film or a silicon nitride film, other than a silicon oxide film, may be used. Moreover, PSG film, BPSG film, PAE (poly aryleneether) system film, HSQ (hydrogen silsesquioxane) system film, MSQ (methyl silsesquioxane) system film, PCB system film, CF system film, SiOC system film, a low-k organic film such as SiOF system film, or porous film thereof, other than the SOG (Spin On Glass) film may be used as the insulating film 41.

Here, by burying the insulating film 41 in the cavity 40 in between the semiconductor substrate 31 and second semiconductor layer 36 with a CVD method, it is possible to bury the cavity 40 in between the semiconductor substrate 31 and second semiconductor layer 36 with material other than the oxide film, while preventing the film reduction of the second semiconductor layer 36. For this reason, it is possible to attain thicker-film of the insulator to be arranged in the back face side of the second semiconductor layer 36, and is possible to reduce the dielectric constant, and the parasitic capacitance of the back face side of the second semiconductor layer 36 can be reduced.

Moreover, after forming the insulating film 41 in the whole surface of the semiconductor substrate 31, high temperature annealing at 1000° C. or more may be carried out. Accordingly, it is possible to reflow the insulating film 41, relax the stress of the insulating film 41, and reduce the interface state density in the boundary with the second semiconductor layer 36. Moreover, the insulating film 41 may be formed as to bury the cavity 40 completely, or may be formed so that a part of the cavity 40 may remain. Moreover, when burying the cavity 40 in between the semiconductor substrate 31 and second semiconductor layer 36 with the insulating film 41, thermal oxidation of the semiconductor substrate 31 and second semiconductor layer 36 may be carried out.

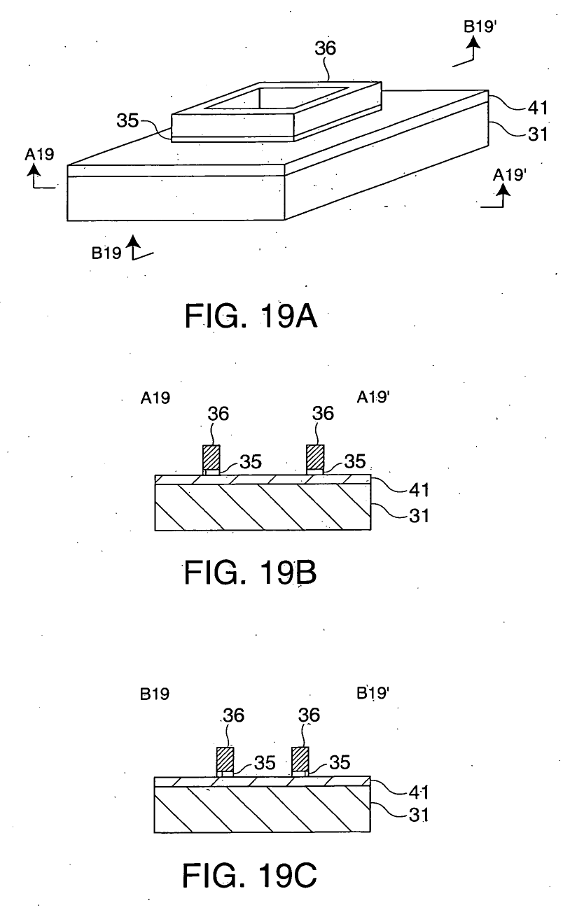

Next, as shown in FIG. 19, by thin-filming the insulating film 41 with a method, such as etch back or CMP (chemical mechanical polish) of the insulating film 41, and by etching the insulating film 34 and 35, the surface of the second semiconductor layer 36 is exposed while leaving the insulating film 41 on the semiconductor substrate 31.

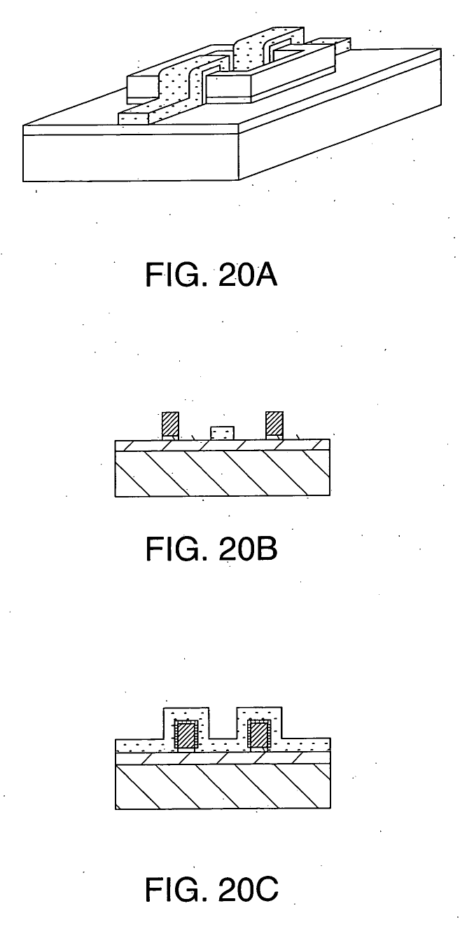

Next, as shown in FIG. 20, a gate insulating film 42 is formed in the surface of the second semiconductor layer 36 by carrying out the thermal oxidation of the surface of the second semiconductor layer 36. Then, a polycrystal silicon layer is formed on the second semiconductor layer 36, in which the gate insulating film 42 is formed, with a method such as CVD. Then, by patterning the polycrystal silicon layer using a photo lithography technique and etching technique, the gate electrode 43 arranged as to straddle on the second semiconductor layer 36 through the side wall of the second semiconductor layer 36 is formed on the insulating film 41.

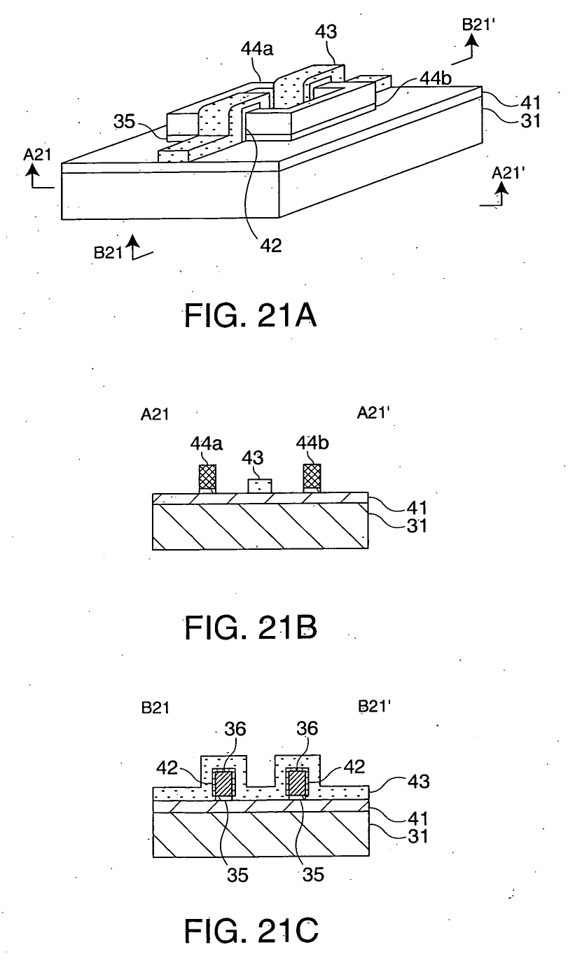

Next, as shown in FIG. 21, by ion implanting impurities, such as As, P, and B, in the second semiconductor layer 36 using the gate electrode 43 as a mask, source/drain layers 44a and 44b arranged on the sides of the gate electrode 43, respectively, are formed in the second semiconductor layer 36.

Accordingly, it is possible, without using a SOI substrate, to arrange on the insulating film 41 the second semiconductor layer 36, which has the film formation face on the side wall, the film formation face being formed with epitaxial-growth, and the channel can be given on the film formation face of the second semiconductor layer 36 that does not receive damage due to dry etching. For this reason, in addition to securing the current drive capability, the integration degree of SOI transistors can be improved and the stable and excellent electrical characteristics can be obtained while attaining the cost reduction of SOI transistors.

In addition, in the above-described embodiments, there has been described a method for forming, in the first semiconductor layer 32, the protrusion 33 that exposes the side wall of the first semiconductor layer 32 in order to film-form the second semiconductor layer 36 on the side wall of the first semiconductor layer 32 formed on the semiconductor substrate 31, however, the third semiconductor layer may be formed on the side wall of the second semiconductor layer by selectively epitaxial-growing the second semiconductor layer in a part of the region on the first semiconductor layer, and by epitaxial-growing the third semiconductor layer on this second semiconductor layer. In this case, the compositions of the first semiconductor layer and second semiconductor layers may be the same or may be different if the etching rate of the third semiconductor layer is lower than the first semiconductor layer and second semiconductor layer.

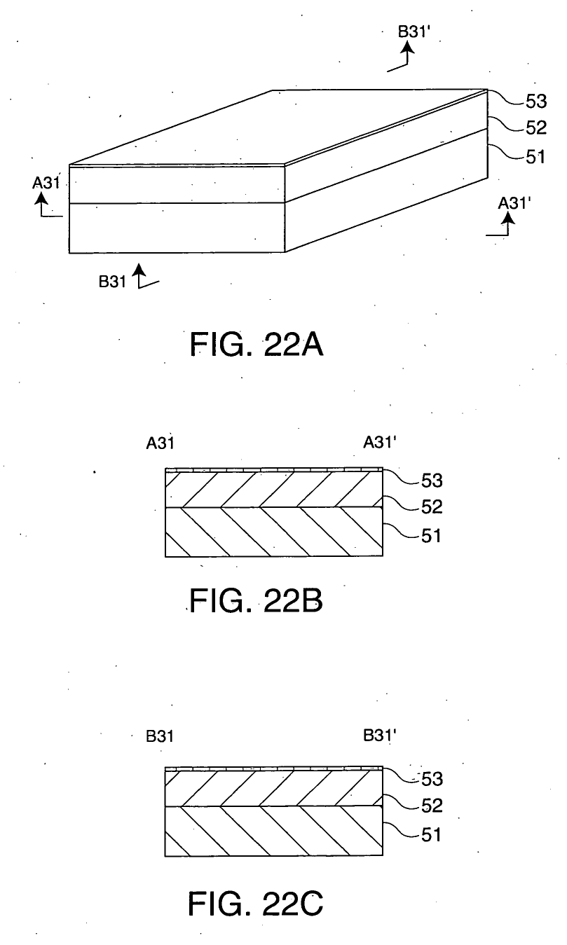

FIG. 22A through FIG. 28A are perspective views showing the manufacturing method of a semiconductor device concerning a fourth embodiment of the invention, FIG. 22B through FIG. 28B are sectional views cut at A31-A37′ to A31-A37′ lines of FIG. 22A through FIG. 28A, respectively, and FIG. 22C through FIG. 28C are sectional views cut at B31-B37′ to B31-B37′ lines of FIG. 22A through FIG. 28A, respectively.

In FIG. 22, a first semiconductor layer 52 is film-formed on a semiconductor substrate 51 with epitaxial-growth. Then, an insulating film 53 is formed on the first semiconductor layer 52 with a method such as CVD.

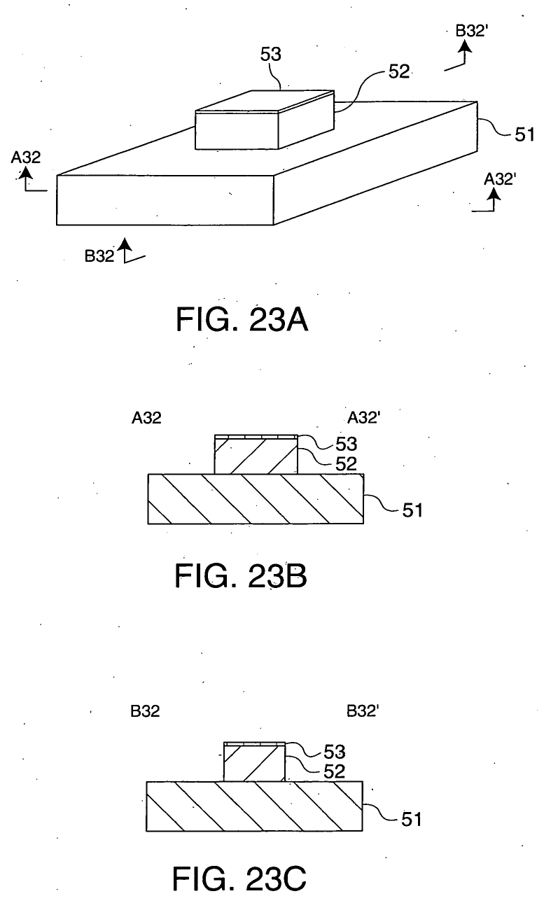

Next, as shown in FIG. 23, by patterning the insulating film 53 and first semiconductor layer 52 using a photo lithography technique and etching technique, a protrusion that exposes the side wall of the first semiconductor layer 52 is formed in the first semiconductor layer 51. Here, in the case where the protrusion that exposes the side wall of the first semiconductor layer 52 is formed onto the semiconductor substrate 51, the semiconductor substrate 51 around the protrusion of the first semiconductor layer 52 is cause to be exposed.

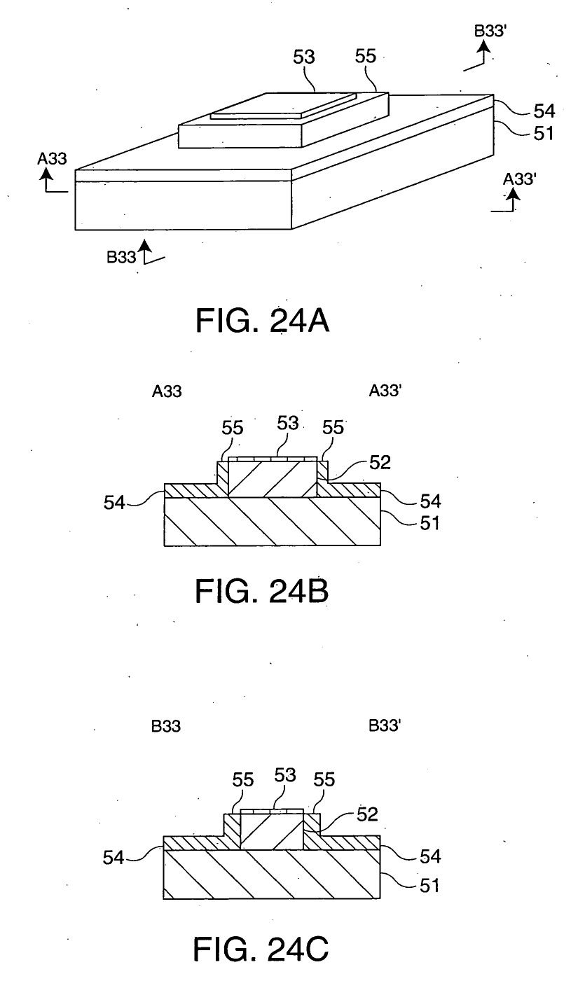

Next, as shown in FIG. 24, a second semiconductor layer 55 is film-formed on the side wall of the protrusion provided in the first semiconductor layer 52 by using a selective epitaxial-growth. Here, because the semiconductor substrate 51 around the protrusion of the first semiconductor layer 52 is exposed, when the second semiconductor layer 55 is film-formed on the side wall of the protrusion provided in the first semiconductor layer 52, the second semiconductor layer 54 is film-formed also on the surface of the semiconductor substrate 51. Moreover, because in the selective epitaxial-growth of the second semiconductor layers 54 and 55, the second semiconductor layers 54 and 55 are not film-formed on the insulating film 53, the second semiconductor layers 54 and 55 can be formed only on the side wall of the protrusion provided in the first semiconductor layer 52, and in the surface of the semiconductor substrate 51.

In addition, for the first semiconductor layer 52, the quality of material with the etching rate higher than the semiconductor substrate 51 and second semiconductor layers 54 and 55 may be used, and for the quality of material of the semiconductor substrate 51, the first semiconductor layer 52, and the second semiconductor layers 54 and 55, for example, combinations selected from Si, Ge, SiGe, SiC, SiSn, PbS, GaAs, InP, GaP and GaN, or ZnSe may be used. In particular, if the semiconductor substrate 51 is Si, it is preferable to use SiGe as the first semiconductor layer 52 and use Si as the second semiconductor layers 54 and 55.

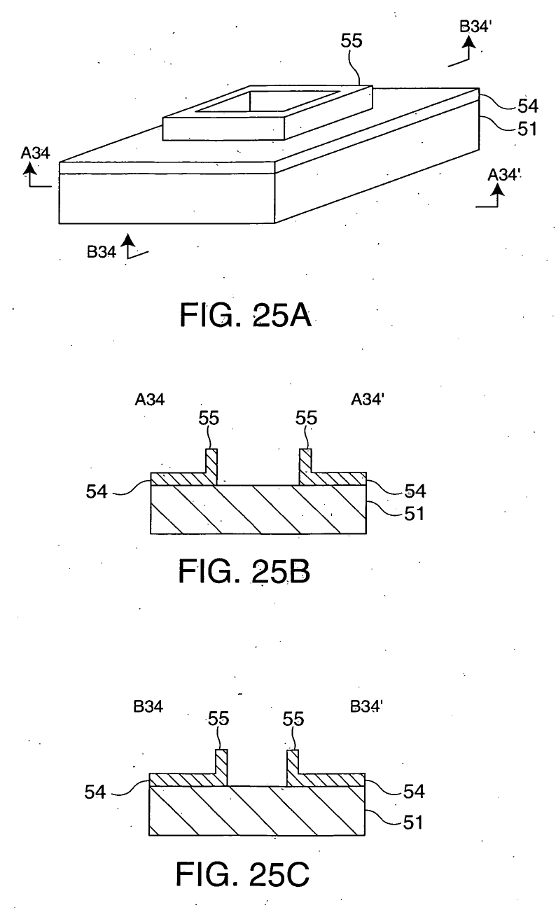

Next, as shown in FIG. 25, after removing the insulating film 53 on the first semiconductor layer 52, the first semiconductor layer 52 is etch-removed by contacting the etching gas or etchant with the first semiconductor layer 52. In addition, it is preferable to use a fluoride nitric acid as the etchant for the first semiconductor layer 52 if the second semiconductor layers 54 and 55 are made of Si and the first semiconductor layer 52 is made of SiGe.

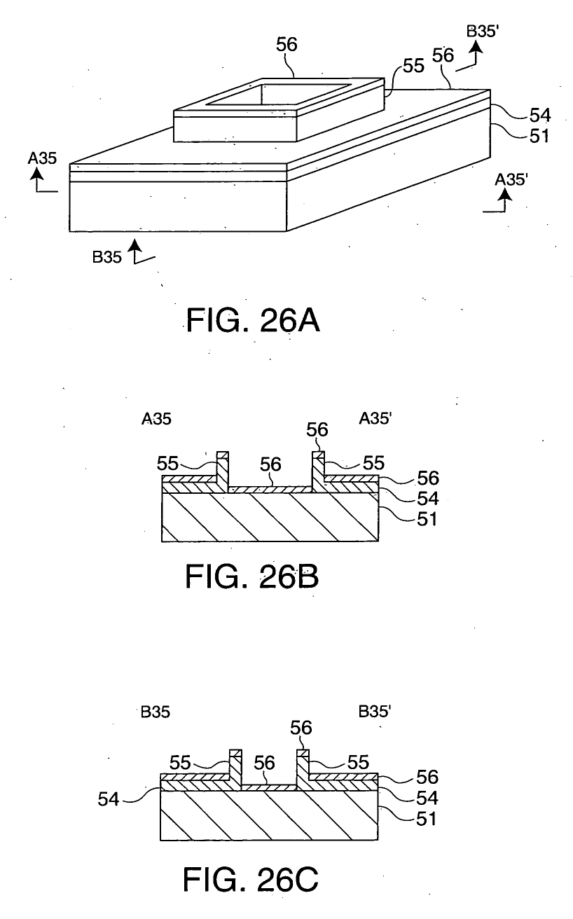

Next, as shown in FIG. 26, the insulating film 56 is film-formed on the semiconductor substrate 51 and on the second semiconductor layer 55 using an anisotropic film formation method such as sputter so that the insulating film 56 may not adhere to the side wall of the second semiconductor layer 55. In addition, in forming the insulating film 56 on the semiconductor substrate 51 and on the second semiconductor layer 55, if the insulating film 56 adheres to the side wall of the second semiconductor layer 55, then isotropic etching such as wet etching may be carried out thereby to remove the insulating film 56 adhered to the side wall of the second semiconductor layer 55, while leaving the insulating film 56 on the semiconductor substrate 51 and second semiconductor layer 56.

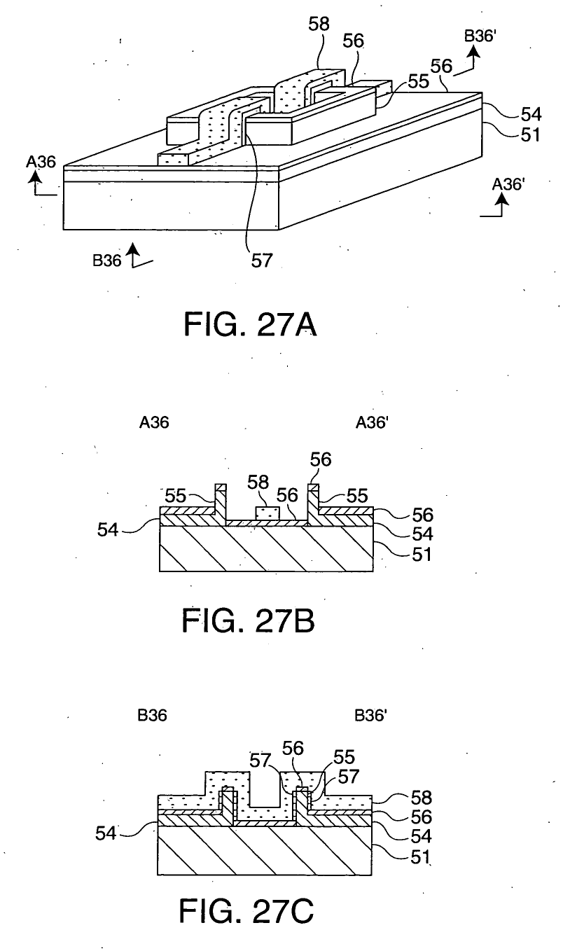

Next, as shown in FIG. 27, a gate insulating film 57 is formed in the surface of the second semiconductor layer 55 by carrying out the thermal oxidation of the surface of the second semiconductor layer 55. Then, a polycrystal silicon layer is formed, with a method such as CVD, on the second semiconductor film 55, in which the gate insulating layer 57 is formed. Then, by patterning the polycrystal silicon layer using a photo lithography technique and etching technique, a gate electrode 58 arranged as to straddle on the second semiconductor layer 55 through the side wall of the second semiconductor layer 55 is formed on the insulating film 56.

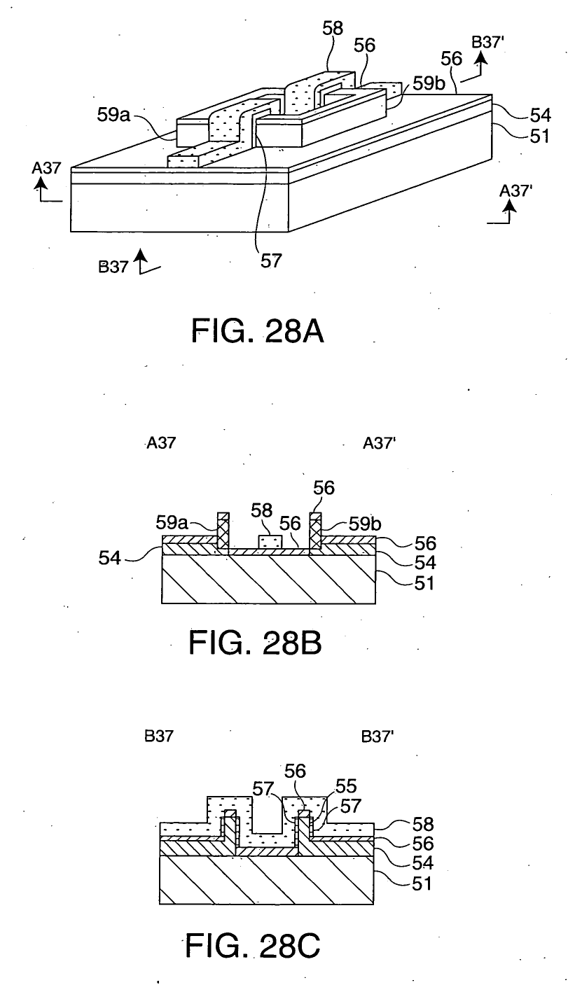

Next, as shown in FIG. 28, by ion implanting impurities, such as As, P, and B, in the second semiconductor layer 55 using the gate electrode 58 as a mask, source/drain layers 59a and 59b arranged on the sides of the gate electrode 58, respectively, are formed in the second semiconductor layer 16.

Accordingly, even in the case where the semiconductor substrate 51 is used as the base layer of the first semiconductor layer 52, it is possible to epitaxial-grow the second semiconductor layer 55 on the side wall of the first semiconductor layer 52, and give the channel onto the film formation face of the second semiconductor layer 55, which is film-formed on the side wall of the first semiconductor layer 52. For this reason, also in the case where the side wall of the second semiconductor layer 55 is caused to have a channel, it is possible, without using an SOI substrate, to prevent damages due to the dry etching from reaching the channel, and control, with epitaxial-growth, the film thickness of the second semiconductor layer 55, in which the channel is to be formed. Consequently, in addition to securing the current drive capability, the integration degree of transistors can be improved, and the stable and excellent electrical characteristics can be obtained while suppressing the cost increase.

The entire disclosure of Japanese Patent Application No. 2005-054612, filed Feb. 28, 2005 is expressly incorporated by reference herein.

What is claimed is:

1. A semiconductor device comprising:
a semiconductor layer having a film formation face in a side wall, the side wall being film-formed with epitaxial-growth;
a gate electrode arranged on the side wall of the semiconductor layer;
a source layer arranged in one side of the gate electrode, the source layer being formed in the semiconductor layer; and
a drain layer arranged in other side of the gate electrode, the drain layer being formed in the semiconductor layer.

2. The semiconductor device according to claim 1, wherein the semiconductor layer is arranged on an insulating layer.

3. The semiconductor device according to claim 1, wherein the semiconductor layer is a distortion semiconductor layer.

4. The semiconductor device according to claim 1, wherein the gate electrode is formed in both side walls of the semiconductor layer as to straddle on the semiconductor layer.

5. The semiconductor device according to claim 1, wherein the semiconductor layer is in the shape of a protrusion, a fin, a box seat or a mesh.

6. A method for manufacturing semiconductor devices, the method comprising:
patterning a first semiconductor layer formed on an insulator thereby to expose a side wall of the first semiconductor layer;
film-forming a second semiconductor layer on a side wall of the first semiconductor layer with epitaxial-growth;
removing the first semiconductor layer from the insulator while leaving the second semiconductor layer on the insulator;
forming a gate electrode on a film formation face of the second semiconductor layer; and
forming in the second semiconductor layer a source layer arranged on one side of the gate electrode and a drain layer arranged on other side of the gate electrode.

7. The method for manufacturing semiconductor devices according to claim 6, further comprising, prior to film-forming the second semiconductor layer on a side wall of the first semiconductor layer, carrying out heat treatment to a first semiconductor layer formed on the insulator thereby to relax the first semiconductor layer.

8. A method for manufacturing semiconductor devices, the method comprising:
film-forming a first semiconductor layer on a base semiconductor layer that is formed on an insulator with epitaxial-growth;
patterning the base semiconductor layer and the first semiconductor layer thereby to expose side walls of the base semiconductor layer and the first semiconductor layer;
film-forming a second semiconductor layer on the side wall of the first semiconductor layer with epitaxial-growth;
removing the first semiconductor layer from the insulator while leaving the second semiconductor layer on the insulator;
forming a gate electrode on a film formation face of the second semiconductor layer; and
forming in the second semiconductor layer a source layer arranged on one side of the gate electrode and a drain layer arranged on other side of the gate electrode.

9. The method for manufacturing semiconductor devices according to claim 8, further comprising thermal-oxidizing the base semiconductor layer after removing the first semiconductor layer.

10. The method for manufacturing semiconductor devices according to claim 6, further comprising forming a wiring layer that is coupled to the source layer or the drain layer as to bite into the second semiconductor layer.
